(19) United States
(12) Patent Application Publication
(10) Pub. No.: US 2026/0096124 A1
(43) Pub. Date: Apr. 2, 2026

(54) MANUFACTURING METHOD OF SEMICONDUCTOR DEVICE

(71) Applicant: United Semiconductor (Xiamen) Co., Ltd., Xiamen (CN)

(72) Inventors: Jian Liu, Xiamen (CN); Chen Chen, Singapore (SG); Jinjian Ouyang, Xiamen (CN); Chin-Chun Huang, Hsinchu County (TW); Wen Yi Tan, Xiamen (CN)

(73) Assignee: United Semiconductor (Xiamen) Co., Ltd., Xiamen (CN)

(21) Appl. No.: 18/929,603

(22) Filed: Oct. 28, 2024

(30) Foreign Application Priority Data
Sep. 30, 2024 (CN) 202411387920.3

(51) Int. Cl. H01L 29/66; H01L 21/02; H01L 21/265; H01L 21/311; H01L 27/088

(52) U.S. Cl. CPC H10D 30/0227; H10D 84/83; H10P 14/69215; H10P 30/204; H10P 30/21; H10P 50/73

(57) ABSTRACT

A manufacturing method of a semiconductor device includes following steps. A semiconductor substrate including a first portion in a low voltage device region and a second portion in a middle voltage device region is provided. A first gate structure and a second gate structure are formed above the first portion and the second portion, respectively. An implantation process is performed for forming a first source/drain doped region in the first portion and a second source/drain doped region in the second portion concurrently. A first oxide layer and a second oxide layer are located above the first portion and the second portion during the implantation process, respectively. The first source/drain doped region is formed under the first oxide layer. The second source/drain doped region is formed under the second oxide layer. A thickness of the second oxide layer is greater than or substantially equal to that of the first oxide layer.

### BACKGROUND OF THE INVENTION

### 1. Field of the Invention

The present invention relates to a manufacturing method of a semiconductor device, and more particularly, to a manufacturing method of a semiconductor device including device regions for different operation voltages.

### 2. Description of the Prior Art

In the integrated circuits, transistors may be different from one another in structure for different operation voltages. For example, the transistors for relatively low operation voltage may be applied in core devices, input/output (I/O) devices, and so on. The transistors capable of high voltage processing may be applied in high operation voltage environment such as CPU power supply, power management system, AC/DC converter, and high-power or power amplifier. In the embedded high voltage (eHV) process, transistor elements for different operation voltages (such as a high voltage transistor, a middle voltage transistor, and a low voltage transistor) may be disposed within one chip for the product specification, and the structures and manufacturing method of the transistors are partially different from one another. Therefore, how to improve the manufacturing process integration of the different transistor structures through structural design and/or process design so as to improve manufacturing yield and/or satisfy product specification is an ongoing research direction for people in related fields.

### SUMMARY OF THE INVENTION

A manufacturing method of a semiconductor device is provided in the present invention. By controlling thicknesses of oxide layers located on a semiconductor substrate within device regions for different operation voltages, source/drain doped regions in the device regions for different operation voltages may be formed by the same implantation process, and purposes of process simplification and/or manufacturing cost reduction may be achieved accordingly.

According to an embodiment of the present invention, a manufacturing method of a semiconductor device is provided. The manufacturing method includes the following steps. A semiconductor substrate is provided, and the semiconductor substrate includes a first portion located within a low voltage device region and a second portion located within a middle voltage device region. A first gate structure and a second gate structure are formed above the first portion and the second portion, respectively. An implantation process is performed for forming a first source/drain doped region in the first portion and forming a second source/drain doped region in the second portion concurrently. A first oxide layer is located above the first portion and a second oxide layer is located above the second portion during the implantation process. The first source/drain doped region is formed under the first oxide layer, the second source/drain doped region is formed under the second oxide layer, and a thickness of the second oxide layer is greater than or substantially equal to a thickness of the first oxide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 are schematic drawings illustrating a manufacturing method of a semiconductor device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, and FIG. 5 is a schematic drawing in a step subsequent to FIG. 4.

FIGS. 6-8 are schematic drawings illustrating a manufacturing method of a semiconductor device according to a second embodiment of the present invention, wherein FIG. 7 is a schematic drawing in a step subsequent to FIG. 6, and FIG. 8 is a schematic drawing in a step subsequent to FIG. 7.

### DETAILED DESCRIPTION

The present invention has been particularly shown and described with respect to certain embodiments and specific features thereof. The embodiments set forth herein below are to be taken as illustrative rather than limiting. It should be readily apparent to those of ordinary skill in the art that various changes and modifications in form and detail may be made without departing from the spirit and scope of the present invention.

Before the further description of the preferred embodiment, the specific terms used throughout the text will be described below.

The terms “on,” “above,” and “over” used herein should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

The ordinal numbers, such as “first”, “second”, etc., used in the description and the claims are used to modify the elements in the claims and do not themselves imply and represent that the claim has any previous ordinal number, do not represent the sequence of some claimed element and another claimed element, and do not represent the sequence of the manufacturing methods, unless an addition description is accompanied. The use of these ordinal numbers is only used to make a claimed element with a certain name clear from another claimed element with the same name.

The term “etch” is used herein to describe the process of patterning a material layer so that at least a portion of the material layer after etching is retained. When “etching” a material layer, at least a portion of the material layer is retained after the end of the treatment. In contrast, when the material layer is “removed”, substantially all the material layer is removed in the process. However, in some embodiments, “removal” is considered to be a broad term and may include etching.

The term “forming” or the term “disposing” are used hereinafter to describe the behavior of applying a layer of material to the substrate. Such terms are intended to describe any possible layer forming techniques including, but not limited to, thermal growth, sputtering, evaporation, chemical vapor deposition, epitaxial growth, electroplating, and the like.

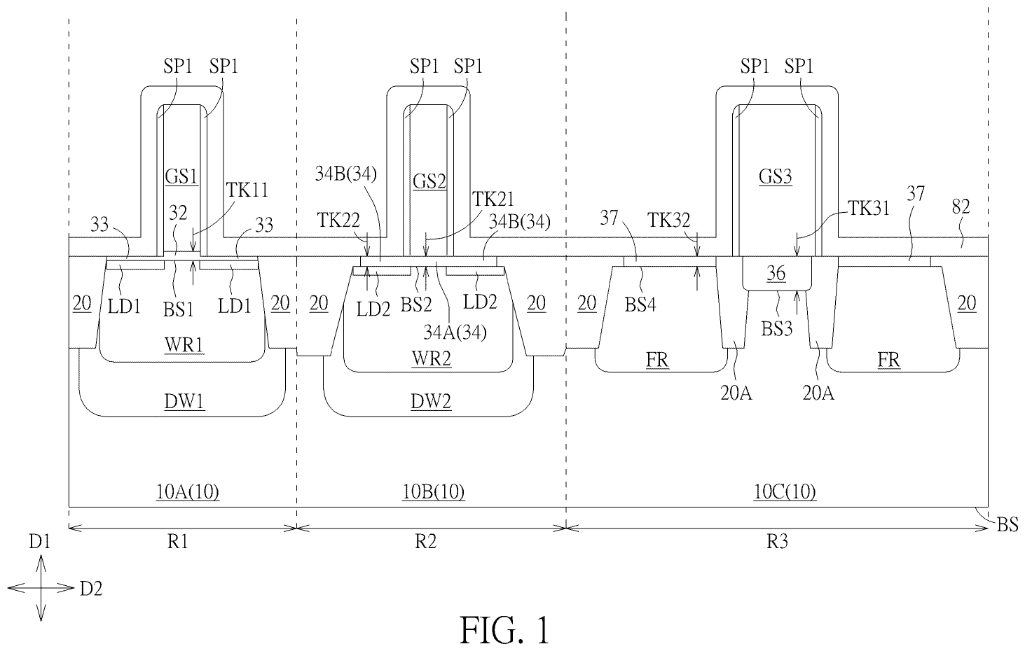

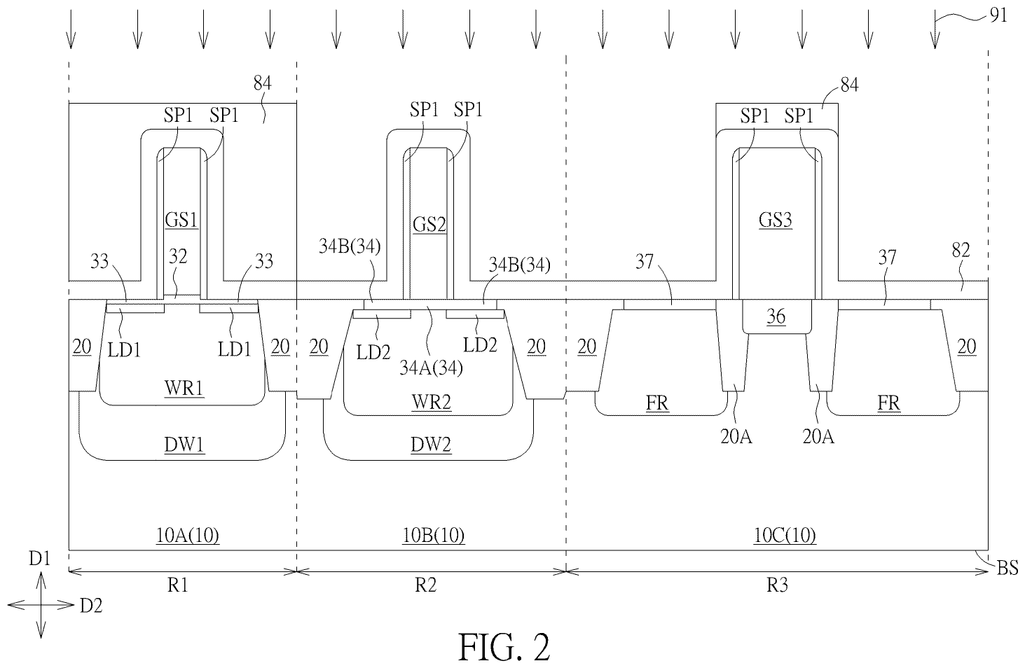

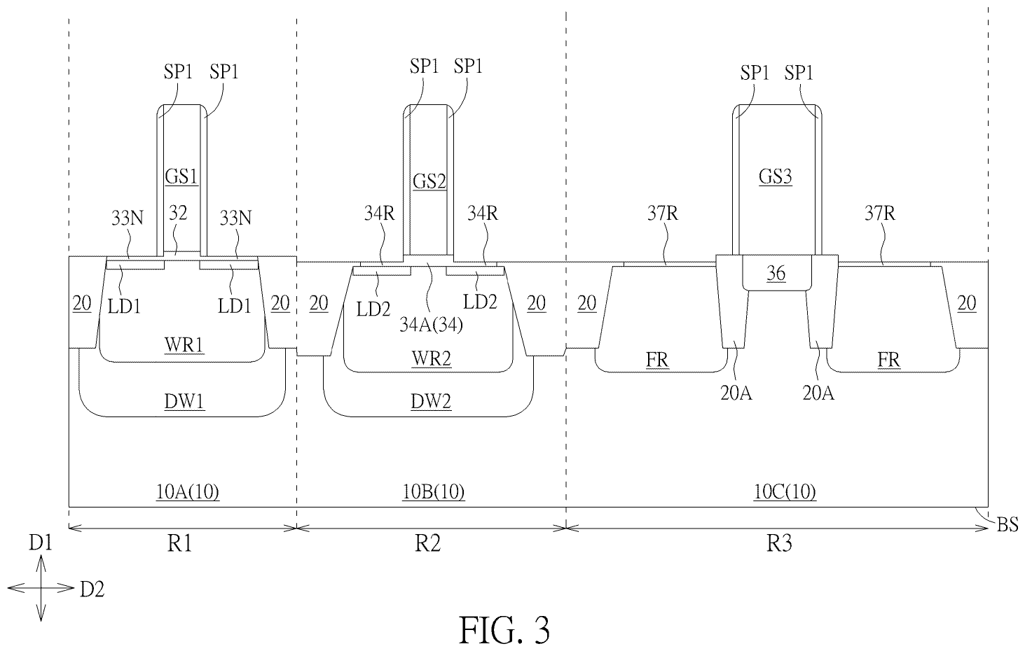

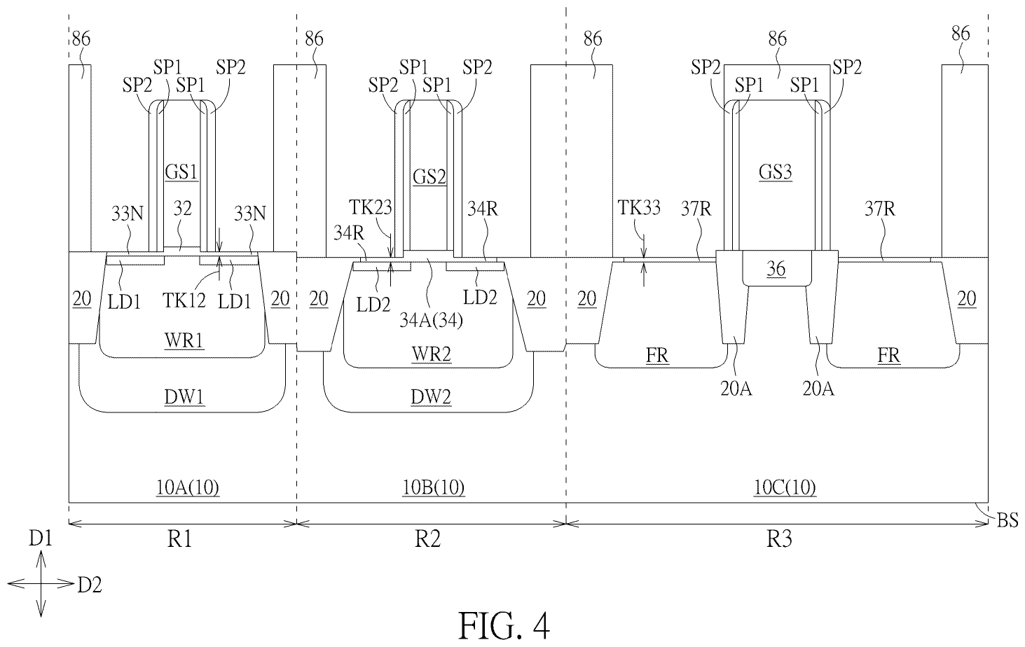

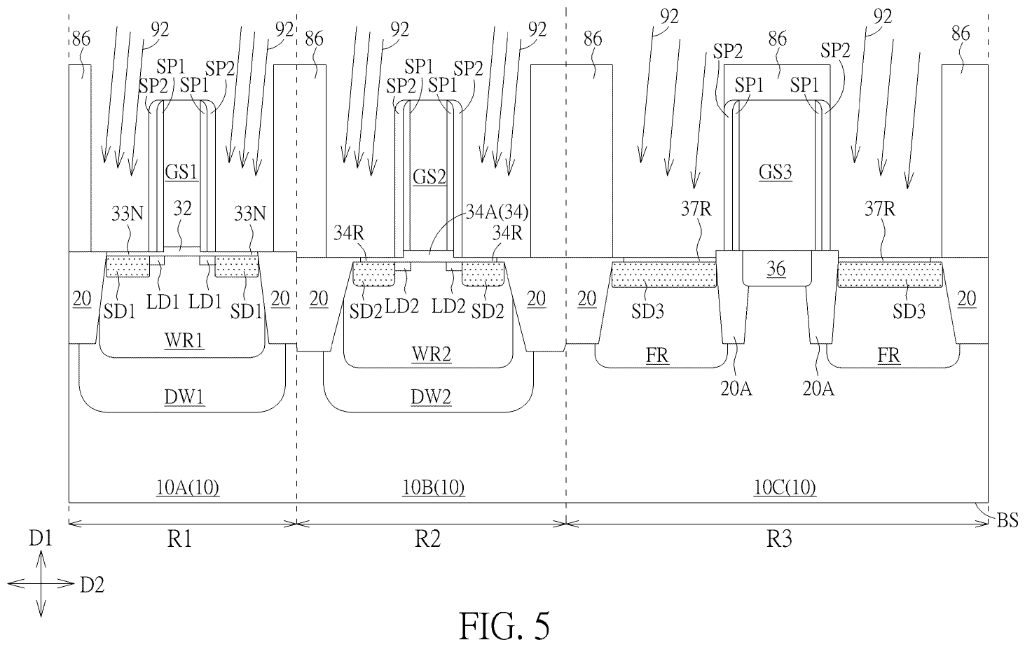

Please refer to FIGS. 1-5. FIGS. 1-5 are schematic drawings illustrating a manufacturing method of a semiconductor device according to a first embodiment of the present invention, wherein FIG. 2 is a schematic drawing in a step subsequent to FIG. 1, FIG. 3 is a schematic drawing in a step subsequent to FIG. 2, FIG. 4 is a schematic drawing in a step subsequent to FIG. 3, and FIG. 5 is a schematic drawing in a step subsequent to FIG. 4. The manufacturing method of the semiconductor device is provided in this embodiment and includes the following steps. Firstly, a semiconductor substrate 10 is provided, and the semiconductor substrate 10 includes a first portion 10A located within a low voltage device region R1 and a second portion 10B located within a middle voltage device region R2. A first gate structure (such as a gate structure GS1) and a second gate structure (such as a gate structure GS2) are then formed above the first portion 10A and the second portion 10B, respectively. Subsequently, as shown in FIG. 5, an implantation process 92 is performed for forming a first source/drain doped region (such as a source/drain doped region SD1) in the first portion 10A and forming a second source/drain doped region (such as a source/drain doped region SD2) in the second portion 10B concurrently. A first oxide layer (such as a first oxide layer 33N) is located above the first portion 10A and a second oxide layer (such as a second oxide layer 34R) is located above the second portion 10B during the implantation process 92. The source/drain doped region SD1 is formed under the first oxide layer 33N, the source/drain doped region SD2 is formed under the second oxide layer 34R, and a thickness of the second oxide layer 34R is greater than or substantially equal to a thickness of the first oxide layer 33N. By controlling the thickness of the second oxide layer 34R in the middle voltage device region R2, the source/drain doped region SD1 located in the low voltage device region R1 and the source/drain doped region SD2 located in the middle voltage device region R2 may be formed concurrently by the same implantation process, and purposes of process simplification and/or manufacturing cost reduction may be achieved accordingly.

As shown in FIG. 1, a vertical direction D1 may be regarded as a thickness direction of the semiconductor substrate 10. The semiconductor substrate 10 may have a top surface and a bottom surface BS opposite to the top surface in the vertical direction D1, and the gate structure GS1 and the gate structure GS2 described above may be formed at the side of the top surface of the semiconductor substrate 10. A horizontal direction substantially orthogonal to the vertical direction D1 (such as a horizontal direction D2, but not limited thereto) may be substantially parallel with the bottom surface BS, but not limited thereto. In this description, a distance between the bottom surface BS of the semiconductor substrate 10 and a relatively higher location and/or a relatively higher part in the vertical direction D1 may be greater than a distance between the bottom surface BS of the semiconductor substrate 10 and a relatively lower location and/or a relatively lower part in the vertical direction D1. The bottom or a lower portion of each component may be closer to the bottom surface BS of the semiconductor substrate 10 in the vertical direction D1 than the top or upper portion of this component. Another component disposed above a specific component may be regarded as being relatively far from the bottom surface BS of the semiconductor substrate 10 in the vertical direction D1, and another component disposed under a specific component may be regarded as being relatively close to the bottom surface BS of the semiconductor substrate 10 in the vertical direction D1. It is worth noting that, in this description, a top surface of a specific component may include the topmost surface of this component in the vertical direction D1, and a bottom surface of a specific component may include the bottommost surface of this component in the vertical direction D1, but not limited thereto. Additionally, in this description, the condition that a certain component is disposed between two other components in a specific direction may include but is not limited to a condition that the certain component is sandwiched between the two other components in the specific direction.

Specifically, the manufacturing method in this embodiment may include but is not limited to the following steps and/or the following features. As shown in FIG. 1, the semiconductor substrate 10 may include a silicon base substrate, a silicon germanium semiconductor substrate, a silicon-on-insulator (SOI) substrate, or a semiconductor substrate made of other suitable materials. In some embodiments, the semiconductor substrate 10 may further include a third portion 10C located within a high voltage device region R3, and the manufacturing method may further include forming a third gate structure (such as a gate structure GS3) above the third portion 10C of the semiconductor substrate 10. In some embodiments, the gate structure GS1, the gate structure GS2, and the gate structure GS3 may be gate structures in a low voltage transistor, a middle voltage transistor, and a high voltage transistor with different operation voltages, respectively. Each gate structure may include a gate dielectric layer and a gate electrode, the gate dielectric layer may include a high dielectric constant (high-k) dielectric material or other suitable dielectric materials, and the gate electrode may include a non-metallic electrically conductive material (such as doped polysilicon) or a metallic electrically conductive material, such as a metal gate structure composed of a work function layer and a low electrical resistivity layer stacked with one another, but not limited thereto. Additionally, in some embodiments, the gate structure described above may be replaced with a metal gate and a gate dielectric layer in subsequent processes (such as a replacement metal gate process), and the gate structure GS1, the gate structure GS2, and the gate structure GS3 may also be regarded as dummy gate structures including a dummy gate material, such as polysilicon, but not limited thereto.

In some embodiments, an isolation structure 20, an isolation structure 20A, lightly doped regions (such as a lightly doped region LD1 and a lightly doped region LD2), doped well regions (such as a deep well region DW1, a deep well region DW2, a well region WR1, and a well region WR2), and a doped region FR may be formed in the semiconductor substrate 10. The isolation structure 20 and the isolation structure 20A may include a single layer or multiple layers of insulation materials, such as an oxide insulation material or other suitable insulation materials. The isolation structure 20 may be used to isolate active areas corresponding to different transistor structures from one another, and the bottom of the isolation structure 20 located within the middle voltage device region R2 may be lower than the bottom of the isolation structure 20 located within other device regions in the vertical direction D1 because of the influence of related processes, but not limited thereto. The deep well region DW1 and the well region WR1 may be formed in the first portion 10A of the semiconductor substrate 10. The deep well region DW2 and the well region WR2 may be formed in the second portion 10B of the semiconductor substrate 10. The doped region FR and the isolation structure 20A may be formed in the third portion 10C of the semiconductor substrate 10. The gate structure GS1 may be located above the well region WR1 and the deep well region DW1 in the vertical direction D1, the gate structure GS2 may be located above the well region WR2 and the deep well region DW2 in the vertical direction D1, and the doped region FR and the isolation structure 20A may be located at two opposite sides of the gate structure GS3 in the horizontal direction. The lightly doped region LD1 may be formed in the first portion 10A and located in the well region WR1, and two lightly doped regions LD1 may be located at two opposite sides of the gate structure GS1 in the horizontal direction, respectively. The lightly doped region LD2 may be formed in the second portion 10B and located in the well region WR2, and two lightly doped regions LD2 may be located at two opposite sides of the gate structure GS2 in the horizontal direction, respectively.

In some embodiments, the low voltage device region R1, the middle voltage device region R2, and the high voltage device region R3 may be an n-type low voltage transistor region, an n-type middle voltage transistor region, and an n-type high voltage transistor region, respectively, but not limited thereto. In addition, the semiconductor substrate 10 may include a p-type semiconductor substrate or a semiconductor substrate including a p-type well region, and in this situation, the deep well region DW1 and the deep well region DW2 may be n-type deep well regions, the doped region FR may be an n-type doped region (may be regarded as an n-type doped drift region, for example), the well region WR1 and the well region WR2 may be p-type well regions, and the lightly doped region LD1 and the lightly doped region LD2 may be n-type lightly doped regions, but not limited thereto.

In some embodiments, the manufacturing method of the semiconductor device may further include forming a first gate oxide layer (such as a gate oxide layer 32), a second gate oxide layer (such as a gate oxide layer 34), and a third gate oxide layer (such as a gate oxide layer 36) in the low voltage device region R1, the middle voltage device region R2, and the high voltage device region R3, respectively, and forming a fourth oxide layer (such as an oxide layer 37) in the high voltage device region R3. The gate oxide layer 32 is formed on the first portion 10A of the semiconductor substrate 10, and at least a part of the gate oxide layer 32 is sandwiched between the gate structure GS1 and the first portion 10A in the vertical direction D1. The gate oxide layer 34 is formed on the second portion 10B of the semiconductor substrate 10, and the gate oxide layer 34 may include a first portion 34A and a second portion 34B. The first portion 34A is sandwiched between the gate structure GS2 and the second portion 10B in the vertical direction D1, the second portion 34B is located at two opposite sides of the gate structure GS2 in the horizontal direction (such as the horizontal direction D2, but not limited thereto), and a thickness TK21 of the first portion 34A and a thickness TK22 of the second portion 34B may be substantially equal to each other. The gate oxide layer 36 and the oxide layer 37 are formed on the third portion 10C of the semiconductor substrate 10, the gate oxide layer 36 is sandwiched between the gate structure GS3 and the third portion 10C in the vertical direction D1, and the oxide layer 37 is located at two opposite sides of the gate structure GS3 in the horizontal direction (such as the horizontal direction D2, but not limited thereto) and/or located at two opposite sides of the gate oxide layer 36 in the horizontal direction D2. In some embodiments, the oxide layer 37 and the gate oxide layer 34 may be formed concurrently by the same process, and a thickness TK32 of the oxide layer 37 and a thickness of the gate oxide layer 34 (such as the thickness TK22 of the second portion 34B) may be substantially equal to each other accordingly. In some embodiments, for satisfying different operation voltages, the thickness of the gate oxide layer 34 (such as the thickness TK21 of the first portion 34A and/or the thickness TK22 of the second portion 34B) may be greater than a thickness TK11 of the gate oxide layer 32, and a thickness TK31 of the gate oxide layer 36 may be greater than the thickness of the gate oxide layer 34 (such as the thickness TK21 and/or the thickness TK22). Additionally, in some embodiments, for reducing negative influence of increasing the thickness of the gate oxide layer on other manufacturing processes, at least a portion of the gate oxide layer 34 and at least a portion of the gate oxide layer 36 may be formed in the semiconductor substrate 10. Therefore, a bottom and/or a bottom surface BS2 of the gate oxide layer 34 may be lower than a bottom and/or a bottom surface BS1of the gate oxide layer 32 in the vertical direction D1, and a bottom and/or a bottom surface BS3 of the gate oxide layer 36 may be lower than the bottom and/or the bottom surface BS2 of the gate oxide layer 34 in the vertical direction D1, but not limited thereto.

In some embodiments, an oxide layer 33 may be formed on the first portion 10A of the semiconductor substrate 10. The oxide layer 33 may be located at two opposite sides of the gate structure GS1 in the horizontal direction (such as the horizontal direction D2, but not limited thereto) and directly connected with the gate oxide layer 32, and the lightly doped region LD1 may be formed under the oxide layer 33 in the vertical direction D1. The oxide layer 37 may be located at two opposite sides of the gate structure GS3 in the horizontal direction (such as the horizontal direction D2, but not limited thereto), the doped region FR may be located under the oxide layer 37 in the vertical direction D1, and the isolation structure 20A may be located between the oxide layer 37 and the gate oxide layer 36 for separating the oxide layer 37 from the gate oxide layer 36. The thickness TK32 of the oxide layer 37 may be less than the thickness TK31 of the gate oxide layer 36, and the bottom and/or the bottom surface BS3 of gate oxide layer 36 may be lower than the bottom and/or a bottom surface BS4 of the oxide layer 37 in the vertical direction D1.

In some embodiments, the gate oxide layer 32, the gate oxide layer 34, the gate oxide layer 36, the oxide layer 33, and the oxide layer 37 may include silicon oxide or other suitable oxide dielectric materials (such as an oxide material formed by oxidizing a part of the material of the semiconductor substrate 10, but not limited thereto). In addition, the manufacturing method of the semiconductor device may further include forming a spacer structure SP1 on sidewalls of the gate structure GS1, the gate structure GS2, and the gate structure GS3 and forming a mask layer 82 covering the gate structure GS1, the gate structure GS2, the gate structure GS3, the spacer structure SP1, the isolation structure 20, the isolation structure 20A, the oxide layer 33, the second portion 34B of the gate oxide layer 34, and the oxide layer 37. In some embodiments, the spacer structure SP1 may include a nitride insulation material or other suitable insulation materials, and the mask layer 82 may include a mask material with a material composition different from that of the spacer structure SP1, the oxide layer 33, the gate oxide layer 34, and the oxide layer 37, but not limited thereto.

As shown in FIG. 2, a patterned mask layer 84 may be formed above the semiconductor substrate 10 and an etching process 91 may be performed after the gate oxide layer 32, the gate oxide layer 34, the gate oxide layer 36, and the oxide layer 37 are formed. The patterned mask layer 84 may include photoresist or other suitable mask materials, and the patterned mask layer 84 may be used as an etching mask in the etching process 91. The patterned mask layer 84 may cover the first portion 10A, the mask layer 82 located above the first portion 10A, the gate structure GS1, and the spacer structure SP1 located above the first portion 10A in the vertical direction D1, and the patterned mask layer 84 may cover the gate structure GS3, the spacer structure SP1 located on the gate structure GS3, and the mask layer 82 located on the gate structure GS3 in the vertical direction D1. Therefore, as shown in FIG. 2 and FIG. 3, the first portion 10A of the semiconductor substrate 10 and the gate structure GS1 may be covered by the patterned mask layer 84 during the etching process 91, and at least a part of the gate oxide layer 34 and at least a part of the oxide layer 37 may be etched by the etching process 91. For example, the etching process 91 may be used to generate an etching back and thinning effect to the second portion 34B of the gate oxide layer 34 and the oxide layer 37 without completely removing the second portion 34B of the gate oxide layer 34 and the oxide layer 37. The second portion 34B of the gate oxide layer 34 may be thinned by the etching process 91 to become the second oxide layer 34R described above, and the oxide layer 37 may be thinned by the etching process 91 to become a third oxide layer 37R. In addition, the patterned mask layer 84 may be removed after the etching process 91, a portion of the mask layer 82 (such as a portion without being covered by the patterned mask layer 84) may be removed by the etching process 91, and the remaining mask layer 82 may be removed after the etching process 91. In some embodiments, the oxide layer 33 may be removed by the etching process 91, and the first oxide layer 33N may be regarded as a portion of the oxide layer 33 remaining after the etching process 91 or the first oxide layer 33N may be a native oxide layer formed in the normal environment after the oxide layer 33 is completely removed by the etching process 91.

Subsequently, as shown in FIG. 4 and FIG. 5, a spacer structure SP2 may be formed on the sidewalls of the gate structure GS1, the gate structure GS2, and the gate structure GS3, and a patterned mask layer 86 may be formed above the semiconductor substrate 10. The spacer structure SP2 may be formed on the spacer structure SP1, and the spacer structure SP2 may include a single layer or multiple layers of insulation materials. The spacer structure SP2 formed in the low voltage device region R1 may be located above the first oxide layer 33N in the vertical direction D1, the spacer structure SP2 formed in the middle voltage device region R2 may be located above the second oxide layer 34R in the vertical direction D1, and the spacer structure SP2 formed in the high voltage device region R2 may be located above the isolation structure 20A in the vertical direction D1. The patterned mask layer 86 may include photoresist or other suitable mask materials, and the patterned mask layer 86 may be used as a mask for performing the implantation process 92 described above. The implantation process 92 may be used to form the source/drain doped region SD1, the source/drain doped region SD2, and a third source/drain doped region (such as a source/drain doped region SD3) in the first portion 10A, the second portion 10B, and the third portion 10C of the semiconductor substrate 10, respectively. In other words, the source/drain doped region SD3 may be formed in the third portion 10C of the semiconductor substrate 10 by the implantation process 92, a third oxide layer (such as the third oxide layer 37R) may be located above the third portion 10C of the semiconductor substrate 10 during the implantation process 92, and the source/drain doped region SD3 may be formed under the third oxide layer 37R. The source/drain doped region SD3, the source/drain doped region SD2, and the source/drain doped region SD1 may be doped regions having the same conductivity type and formed concurrently by the implantation process 92, such as n-type doped regions, and the dopants used in the implantation process 92 may include phosphor, arsenic, or other suitable n-type dopants, but not limited thereto.

In some embodiments, a thickness TK12 of the first oxide layer 33N, a thickness TK23 of the second oxide layer 34R, and a thickness TK33 of the third oxide layer 37R may be substantially equal to one another, and the source/drain region SD1, the source/drain region SD2, and the source/drain region SD3 may be formed concurrently by the implantation process 92 accordingly and have the required doped region characteristics (such as doped area, doped concentration, and so forth, but not limited thereto). It is worth noting that, considering feasible process variation control, in this description, the condition that two or more thicknesses are substantially equal to one another may include a condition that the thicknesses are substantially equal to one another with a specific tolerance. For example, the thickness TK 23 of the second oxide layer 34R may be substantially equal to the thickness TK12 of the first oxide layer 33N with a tolerance of ±10%, and the thickness TK33 of the third oxide layer 37R may be substantially equal to the thickness TK23 of the second oxide layer 34R with a tolerance of ±10%, but not limited thereto. In some embodiments, the tolerance described above may also include ±5%, ±15%, or other suitable ranges. When the tolerance is ±10%, the thickness TK23 may range from 0.9 times the thickness TK12 to 1.1 times the thickness TK12, and the thickness TK33 may range from 0.9 times the thickness TK23 to 1.1 times the thickness TK23. In addition, the thickness TK23 of the second oxide layer 34R and the thickness TK33 of the third oxide layer 37R may be respectively less than one-half of the thickness TK21 of the first portion 34A of the gate oxide layer 34. For instance, the thickness TK23 and the thickness TK33 may respectively range from 11.5% of the thickness TK21 to 38% of the thickness TK21, but not limited thereto.

In some embodiments, two source/drain doped regions SD1 may be formed in the well region WR1 and located at two opposite sides of the gate structure GS1 in the horizontal direction (such as the horizontal direction D2, but not limited thereto), two source/drain doped regions SD2 may be formed in the well region WR2 and located at two opposite sides of the gate structure GS2 in the horizontal direction (such as the horizontal direction D2, but not limited thereto), and two source/drain doped regions SD3 may be formed in the two doped regions FR and located at two opposite sides of the gate structure GS3 in the horizontal direction (such as the horizontal direction D2, but not limited thereto). A semiconductor device located in the low voltage device region R1 (such as a low voltage transistor) may include the gate structure GS1, the gate oxide layer 32, the first oxide layer 33N, the well region WR1, the lightly doped regions LD1, and the source/drain doped regions SD1. A semiconductor device located in the middle voltage device region R2 (such as a middle voltage transistor) may include the gate structure GS2, the gate oxide layer 34, the second oxide layer 34R, the well region WR2, the lightly doped regions LD2, and the source/drain doped regions SD2. A semiconductor device located in the high voltage device region R3 (such as a high voltage transistor) may include the gate structure GS3, the gate oxide layer 36, the third gate oxide layer 37R, the isolation structure 20A, the doped regions FR, and the source/drain doped regions SD3. In other words, the source/drain doped region SD1, the source/drain doped region SD2, and the source/drain doped region SD3 may be source/drain doped regions in semiconductor devices with different operation voltages, respectively, and the source/drain doped region SD1, the source/drain doped region SD2, and the source/drain doped region SD3 may be formed concurrently by the same implantation process when the thicknesses of the second oxide layer 34R and the third oxide layer 37R are controlled. Generally, in the advanced embedded high voltage (eHV) process, different reticles (or photomask) are used to form the source/drain doped regions in the low voltage device region and the source/drain doped regions in the middle to high voltage device region separately, and the source/drain doped regions in the low voltage device region and the source/drain doped regions in the middle to high voltage device region may be formed concurrently in the present invention by the same reticle (or photomask) because the thickness of the oxide layer located above the top surface of the source/drain is modified. The purposes of process simplification and/or manufacturing cost reduction may be achieved accordingly.

The following description will detail the different embodiments of the present invention. To simplify the description, the following description will detail the dissimilarities among different embodiments and the identical features will not be redundantly described. In addition, identical components in each of the following embodiments are marked with identical symbols for making it easier to understand the differences between the embodiments.

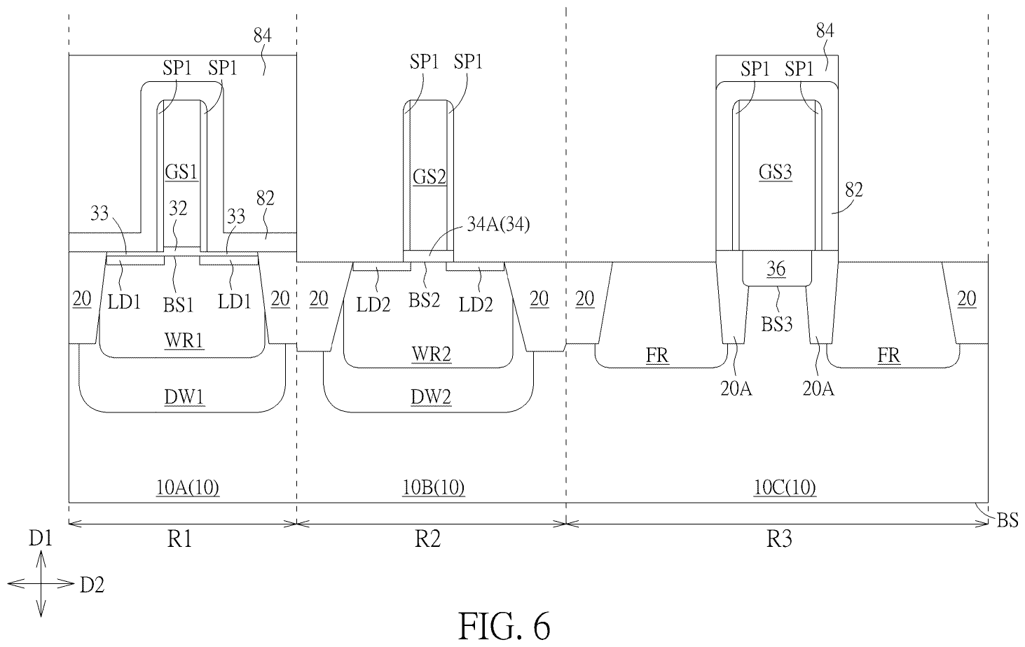

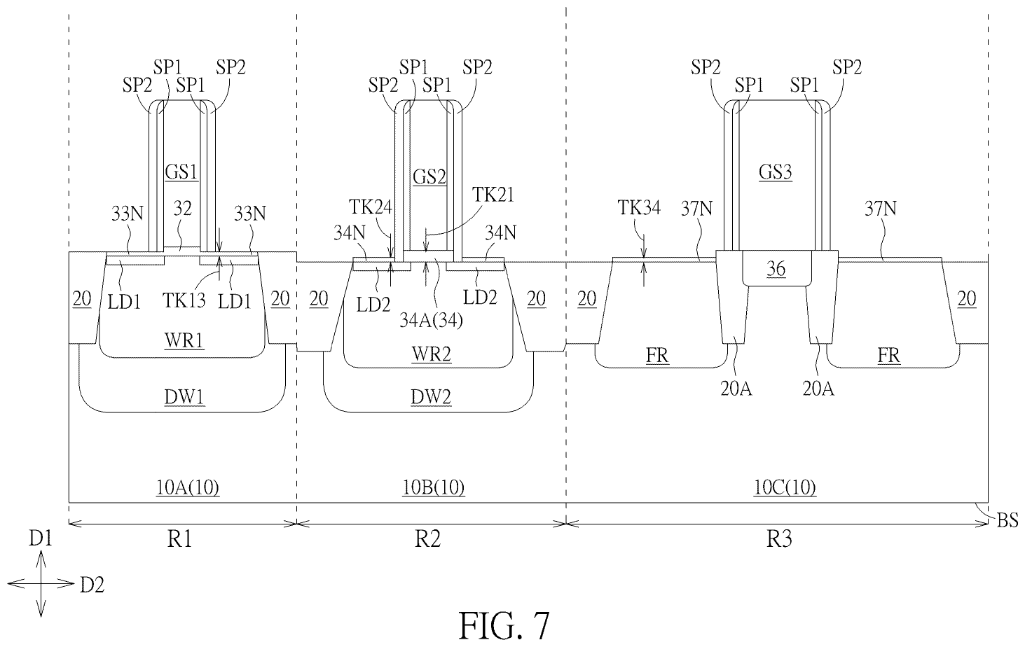

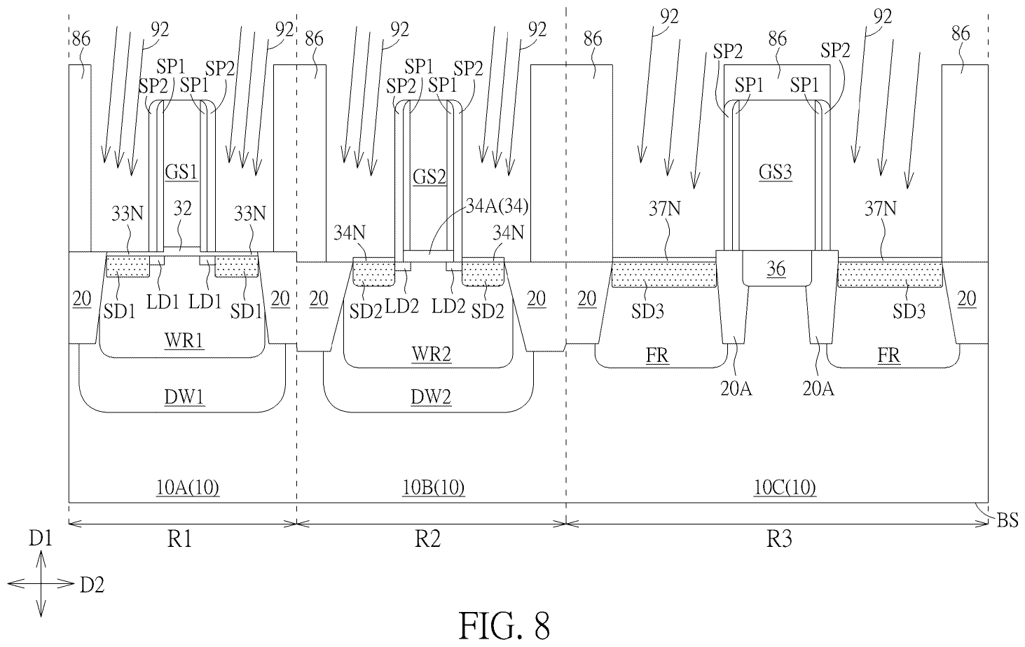

Please refer to FIG. 2 and FIGS. 6-8. FIGS. 6-8 are schematic drawings illustrating a manufacturing method of a semiconductor device according to a second embodiment of the present invention, wherein FIG. 7 is a schematic drawing in a step subsequent to FIG. 6, and FIG. 8 is a schematic drawing in a step subsequent to FIG. 7. In some embodiments, FIG. 6 may be regarded as a schematic drawing in a step subsequent to FIG. 2, but not limited thereto. As shown in FIG. 2 and FIG. 6, in some embodiments, the second portion 34B of the gate oxide layer 34 and the oxide layer 37 may be completely removed by the etching process 91. As shown in FIG. 2, FIG. 6, and FIG. 7, after the etching process 91, the spacer structure SP2, the second oxide layer (such as a second oxide layer 34N), and the third oxide layer (such as a third oxide layer 37N) may be formed. In some embodiments, the second oxide layer 34N and the third oxide layer 37N may be native oxide layers formed after the etching process 91, and a thickness of the first oxide layer 33N (such as a thickness TK13), a thickness TK24 of the second oxide layer 34N, and a thickness TK34 of the third oxide layer 37N may be substantially equal to one another.

As shown in FIG. 7 and FIG. 8, the patterned mask layer 86 may be formed above the semiconductor substrate 10, and the implantation process 92 using the patterned mask layer 86 as a mask may be performed for forming the source/drain doped region SD1, the source/drain doped region SD2, and the source/drain doped region SD3 in the first portion 10A, the second portion 10B, and the third portion 10C of the semiconductor substrate 10, respectively. In the implantation process 92, the first oxide layer 33N is located above the first portion 10A, the second oxide layer 34N is located above the second portion 10B, and the third oxide layer 37N is located above the third portion 10C. The source/drain doped region SD1 is formed under the first oxide layer 33N, the source/drain doped region SD2 is formed under the second oxide layer 34N, and the source/drain doped region SD3 is formed under the third oxide layer 37N. In some embodiments, the thickness TK13 of the first oxide layer 33N, the thickness TK24 of the second oxide layer 34N, and the thickness TK34 of the third oxide layer 37N may be substantially equal to one another with a specific tolerance, and the tolerance may include ±5%, ±10%, ±15%, or other suitable ranges. In addition, the thickness TK24 of the second oxide layer 34N and the thickness TK34 of the third oxide layer 37N may be respectively less than one-half of the thickness TK21 of the first portion 34A of the gate oxide layer 34. For instance, the thickness TK24 and the thickness TK34 may respectively range from 11.5% of the thickness TK21 to 38% of the thickness TK21, but not limited thereto.

To summarize the above descriptions, in the manufacturing method of the semiconductor device, the thicknesses of the oxide layers located above the semiconductor substrate in the device regions of different operation voltages may be controlled for concurrently forming the source/drain doped regions in the device regions of different operation voltages by the same implantation process. The purposes of process simplification and/or manufacturing cost reduction may be achieved accordingly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A manufacturing method of a semiconductor device, comprising:
providing a semiconductor substrate, wherein the semiconductor substrate comprises a first portion located within a low voltage device region and a second portion located within a middle voltage device region;
forming a first gate structure and a second gate structure above the first portion and the second portion, respectively; and
performing an implantation process for forming a first source/drain doped region in the first portion and forming a second source/drain doped region in the second portion concurrently, wherein a first oxide layer is located above the first portion and a second oxide layer is located above the second portion during the implantation process, the first source/drain doped region is formed under the first oxide layer, the second source/drain doped region is formed under the second oxide layer, and a thickness of the second oxide layer is greater than or substantially equal to a thickness of the first oxide layer.

2. The manufacturing method of the semiconductor device according to claim 1, wherein the thickness of the second oxide layer is substantially equal to the thickness of the first oxide layer with a tolerance of ±10%.

3. The manufacturing method of the semiconductor device according to claim 1, further comprising:
forming a first gate oxide layer on the first portion of the semiconductor substrate, wherein at least a part of the first gate oxide layer is sandwiched between the first gate structure and the first portion of the semiconductor substrate in a vertical direction; and
forming a second gate oxide layer on the second portion of the semiconductor substrate, wherein a first portion of the second gate oxide layer is sandwiched between the second gate structure and the second portion of the semiconductor substrate in the vertical direction, a second portion of the second gate oxide layer is located at two opposite sides of the second gate structure in a horizontal direction, and a thickness of the second gate oxide layer is greater than a thickness of the first gate oxide layer.

4. The manufacturing method of the semiconductor device according to claim 3, wherein a bottom of the second gate oxide layer is lower than a bottom of the first gate oxide layer in the vertical direction.

5. The manufacturing method of the semiconductor device according to claim 3, further comprising:
forming a patterned mask layer above the semiconductor substrate and performing an etching process after the first gate oxide layer and the second gate oxide layer are formed, wherein the first portion of the semiconductor substrate and the first gate structure are covered by the patterned mask layer during the etching process, and at least a part of the second gate oxide layer is etched by the etching process.

6. The manufacturing method of the semiconductor device according to claim 5, wherein the second portion of the second gate oxide layer is thinned by the etching process to become the second oxide layer.

7. The manufacturing method of the semiconductor device according to claim 5, wherein the second portion of the second gate oxide layer is completely removed by the etching process.

8. The manufacturing method of the semiconductor device according to claim 7, wherein the second oxide layer is a native oxide layer formed after the etching process.

9. The manufacturing method of the semiconductor device according to claim 5, wherein the semiconductor substrate further comprises a third portion located within a high voltage device region, and the manufacturing method of the semiconductor device further comprises:
forming a third gate structure above the third portion of the semiconductor substrate, wherein a third source/drain doped region is formed in the third portion of the semiconductor substrate by the implantation process, a third oxide layer is located above the third portion of the semiconductor substrate during the implantation process, and the third source/drain doped region is formed under the third oxide layer.

10. The manufacturing method of the semiconductor device according to claim 9, wherein a thickness of the third oxide layer is substantially equal to the thickness of the second oxide layer with a tolerance of ±10%.

11. The manufacturing method of the semiconductor device according to claim 9, wherein the third source/drain doped region, the second source/drain doped region, and the first source/drain doped region are n-type doped regions formed concurrently by the implantation process.

12. The manufacturing method of the semiconductor device according to claim 9, further comprising:
forming a third gate oxide layer on the third portion of the semiconductor substrate, wherein the third gate oxide layer is sandwiched between the third gate structure and the third portion of the semiconductor substrate in the vertical direction, and a thickness of the third gate oxide layer is greater than the thickness of the second gate oxide layer; and
forming a fourth oxide layer on the third portion of the semiconductor substrate, wherein the fourth oxide layer is located at two opposite sides of the third gate oxide layer in the horizontal direction and separated from the third gate oxide layer, and a thickness of the fourth oxide layer is less than the thickness of the third gate oxide layer.

13. The manufacturing method of the semiconductor device according to claim 12, wherein a bottom of the third gate oxide layer is lower than a bottom of the fourth oxide layer and a bottom of the second gate oxide layer in the vertical direction.

14. The manufacturing method of the semiconductor device according to claim 12, wherein the fourth oxide layer is thinned by the etching process to become the third oxide layer.

15. The manufacturing method of the semiconductor device according to claim 12, wherein the fourth oxide layer is completely removed by the etching process.

16. The manufacturing method of the semiconductor device according to claim 15, wherein the third oxide layer is a native oxide layer formed after the etching process.

17. The manufacturing method of the semiconductor device according to claim 3, wherein the thickness of the second oxide layer is less than one-half of a thickness of the first portion of the second gate oxide layer.

18. The manufacturing method of the semiconductor device according to claim 17, wherein the thickness of the second oxide layer ranges from 11.5% of the thickness of the first portion of the second gate oxide layer to 38% of the thickness of the first portion of the second gate oxide layer.
